(19) United States
(12) Patent Application Publication
(10) Pub. No.: US 2026/0248009 A1
(43) Pub. Date: Aug. 20, 2026

(54) COPPER-CERAMIC SUBSTRATE WITH AN UPPER FACE WHICH CAN BE SINTERED

(71) Applicant: HERAEUS ELECTRONICS GMBH & CO. KG, Hanau (DE)

(72) Inventors: Tamira STEGMANN, Hanau (DE); Sven THOMAS, Hanau (DE)

(21) Appl. No.: 19/157,556

(22) PCT Filed: Feb. 12, 2024
(86) PCT No.: PCT/EP2024/053470

§ 371 Date: Aug. 18, 2025

(30) Foreign Application Priority Data
Feb. 23, 2023 (EP) 23158215.6

(51) Int. Cl. H10W 70/692; H10W 70/66; H10W 72/00; H10W 72/30; H10W 90/00

(52) U.S. Cl. CPC H10W 70/692; H10W 70/66; H10W 72/07332; H10W 72/352; H10W 90/734

(57) ABSTRACT

A copper-ceramic substrate comprising: a) a ceramic body and b) a copper layer which is connected to the ceramic body in a planar manner. The copper layer has an upper face, and an energy spectrum, which is obtained during an analysis of the upper face of the copper layer by X-ray photoelectron spectroscopy, exhibits (i) at least one signal S1 which comprises at least one peak P1 with a maximum ranging from 526 eV-538 eV, wherein the at least one peak P1 has an area PF1, and the areas PF1 of all of the peaks P1 of the at least one signal S1 result in a total area GF1, and (ii) at least one signal S2 which comprises at least one peak P2 with a maximum ranging from 0 eV-1400 eV, wherein the at least one peak P2 has an area PF2.

The present invention relates to a copper-ceramic substrate, to the use of a copper-ceramic substrate, and to a method for producing a bonded connection between a copper-ceramic substrate and an electronic component.

Copper-ceramic substrates play an important role in the field of power electronics. They are a crucial element when building electronic assemblies and ensure rapid dissipation of large quantities of heat during operation of said assemblies. Copper-ceramic substrates typically consist of a ceramic layer and a copper layer which is connected to the ceramic layer.

A plurality of methods are known from the prior art for connecting the copper layer to the ceramic layer. In the so-called DCB (“direct copper bonding”) method, a copper foil is provided superficially with a copper compound (usually copper oxide), which has a lower melting point than copper, by reacting copper with a reactive gas (usually oxygen). When the copper foil treated in this way is applied to a ceramic body and the composite is heated, the copper compound melts and wets the surface of the ceramic body, so that a stable cohesive bond is created between the copper foil and the ceramic body. This method is described, for example, in U.S. Pat. No. 3,744,120 A or DE 2319854 C2.

In an alternative method, copper foils can be bonded to ceramic bodies at temperatures of approximately 650 to 1000° C., wherein an active solder is used which contains a metal having a melting point of at least 700° C. (usually silver) and an active metal. The role of the active metal is to react with the ceramic material and to thus facilitate a bonding of the ceramic material to the remaining solder, forming a reaction layer, while the metal having a melting point of at least 700° C. serves to bond said reaction layer to the copper foil. For example, JP4812985 B2 proposes bonding a copper foil to a ceramic body using a solder containing 50 to 89 percent by weight silver, as well as copper, bismuth and an active metal. With this method, it is possible to connect the copper foil firmly to the ceramic body. Alternatively, silver-free active solders can be used to connect copper foils to ceramic bodies. These solders are based, for example, on high-melting metals (in particular copper), low-melting metals (such as bismuth, indium or tin), and active metals (such as titanium). Such a technique is proposed, for example, in DE 102017114893 A1. This technique basically results in a new, independent class of compounds, since the basis of the solders used is formed by another metal (copper instead of silver), which leads to changed material properties and results in an adaptation with regard to the other solder components and modified joining conditions.

In the construction of electronic assemblies, copper-ceramic substrates are usually equipped with electronic components. It is necessary that the electronic component is firmly bonded to the copper-ceramic substrate. Since electronic assemblies are often exposed to high temperatures during operation, the electronic component is often connected to the copper-ceramic substrate using a sintering material that comprises silver. During the sintering process, the silver forms a bonded connection to the surfaces of the electronic component and the copper-ceramic substrate that are to be connected. Due to the high melting point of silver, the resulting compound is temperature-stable. In order to achieve a high bond strength, the surface of the copper-ceramic substrate to be connected is usually coated with a precious metal, in particular silver or gold, before the sintering process. This facilitates bonding of the sintering material, since the silver contained therein can easily diffuse into the precious metal-containing coating of the copper-ceramic substrate. The disadvantage, however, is that coating the copper-ceramic substrate with a precious metal is technically complex and requires additional manufacturing steps. It would therefore be desirable to be able to firmly bond electronic components to copper-ceramic substrates without the surface of the copper-ceramic substrate to be connected being provided with a coating containing precious metals.

Therefore, an object of the present invention is preferably to provide a copper-ceramic substrate which is suitable for a bonded connection to an electronic component.

A further object of the present invention is preferably to provide a copper-ceramic substrate which is suitable for a bonded connection to an electronic component without the need for a precious-metal-containing coating on the surface of the copper-ceramic substrate to be connected.

A contribution to achieving these objects is made by:
a copper-ceramic substrate comprising
a) a ceramic body and
b) a copper layer which is connected to the ceramic body in a planar manner, wherein the copper layer has an upper face,
wherein
an energy spectrum, which is obtained during an analysis of the upper face of the copper layer by X-ray photoelectron spectroscopy, exhibits
(i) at least one signal S1 which comprises at least one peak P1 with a maximum ranging from 526 eV-538 eV, wherein the at least one peak P1 has an area PF1, and the areas PF1 of all of the peaks P1 of the at least one signal S1 result in a total area GF1, and
(ii) at least one signal S2 which comprises at least one peak P2 with a maximum ranging from 0 eV-1400 eV, wherein the at least one peak P2 has an area PF2, and the areas PF2 of all of the peaks P2 of the at least one signal S2 result in a total area GF2,
the ratio GF1/GF2 being at least 0.25.

The invention further provides the use of a copper-ceramic substrate and a method for producing a bonded connection between a copper-ceramic substrate and an electronic component.

The copper-ceramic substrate according to the invention comprises a ceramic body.

The ceramic body is preferably a body formed from ceramic. The body can have any geometry, but is preferably designed as a cuboid. The ceramic body comprises boundary surfaces—in the case of a cuboid, six boundary surfaces. The ceramic body preferably has a primary boundary surface. The primary boundary surface in this document preferably refers to the boundary surface with the greatest surface area, which is connected to the copper layer in a planar manner. The primary boundary surface preferably lies in the main extension plane or runs in parallel therewith. Accordingly, the main extension plane of the ceramic body is understood preferably to be a plane that runs in parallel with the primary boundary surface of the ceramic body or encloses it.

The ceramic of the ceramic body is preferably an insulating ceramic. According to a preferred embodiment, the ceramic is selected from the group consisting of oxide ceramics, nitride ceramics, and carbide ceramics. According to a further preferred embodiment, the ceramic is selected from the group consisting of metal oxide ceramics, silicon oxide ceramics, metal nitride ceramics, silicon nitride ceramics, boron nitride ceramics, and boron carbide ceramics. According to a particularly preferred embodiment, the ceramic is selected from the group consisting of aluminum nitride ceramics, silicon nitride ceramics, and aluminum oxide ceramics (such as ZTA (“zirconia-toughened alumina”) ceramics). According to a further very particularly preferred embodiment, the ceramic body consists of (1) at least one element selected from the group consisting of silicon and aluminum, (2) at least one element selected from the group consisting of oxygen and nitrogen, optionally (3) at least one element selected from the group consisting of (3a) rare earth metals, (3b) metals of the second main group of the periodic table of elements, (3c) zirconium, (3d) copper, (3e) molybdenum and (3f) silicon, and optionally (4) unavoidable impurities. According to yet another very particularly preferred embodiment, the ceramic body is free of bismuth, gallium, and zinc.

The ceramic body preferably has a thickness of 0.05-10 mm, more preferably ranging from 0.1-5 mm, and particularly preferably ranging from 0.15-3 mm.

The copper-ceramic substrate according to the invention comprises a copper layer which is connected to the ceramic body in a planar manner, wherein the copper layer has an upper face.

The copper layer comprises copper. In addition to copper, the copper layer preferably also comprises oxygen, which is present as copper oxide, in particular as copper(I) oxide (Cu₂O) and/or copper (II) oxide (CuO). According to a preferred embodiment, the copper layer therefore comprises copper, oxygen and unavoidable impurities. According to a further preferred embodiment, the proportion of copper is at least 90 percent by weight, more preferably at least 95 percent by weight, even more preferably at least 99 percent by weight and particularly preferably at least 99.9 percent by weight, based on the total weight of the copper layer. According to a further particularly preferred embodiment, the copper layer consists of copper, oxygen and unavoidable impurities.

The copper layer preferably has a thickness ranging from 0.01-10 mm, particularly preferably ranging from 0.03-5 mm, and very particularly preferably ranging from 0.05-3 mm.

The copper layer is preferably connected in a bonded manner to the ceramic body. According to a preferred embodiment, the copper layer is connected to the ceramic body by a method selected from the group consisting of DCB (direct copper bonding) methods and active soldering methods, in particular AMB (active metal brazing) methods.

When connecting a copper layer to a ceramic body by a DCB method, a copper foil is preferably connected to a ceramic body, wherein a melt layer containing a chemical compound comprising copper and a reactive gas, preferably oxygen, is produced on the surface of the copper foil by heating to a temperature ranging from 1025-1083° C., in particular to a temperature of 1071° C. This melt layer forms a eutectic with a melting temperature below the melting temperature of copper, so that by placing the copper foil on the ceramic body and heating it, a positive connection is created between the copper foil and the ceramic body. Such a method is disclosed, for example, in the German patent application DE2319854 A1.

When connecting a copper layer to a ceramic body using an AMB method, an active solder is preferably used to connect a copper foil to a ceramic body. For this purpose, the active solder is preferably positioned between the ceramic body and the copper foil and melted (particularly preferably at a temperature ranging from 800-1000° C.). When the active solder solidifies, a positive connection is formed between the ceramic body and the copper foil. Consequently, the copper layer can also be connected in a planar manner to the ceramic body via a connecting layer. The connecting layer can be, for example, an active solder layer or a diffusion layer. Such a method is disclosed, for example, in European patent application EP153618 A2.

The copper layer is connected to the ceramic body in a planar manner. Accordingly, the copper layer is preferably connected in a planar manner to the primary boundary surface of the ceramic body. The copper layer is preferably not connected to the entire primary boundary surface of the ceramic body. In particular, it can be provided that the primary boundary surface of the ceramic body is larger than the surface of the copper layer connected to the ceramic body. In these cases, the primary boundary surface of the ceramic body protrudes. In addition, it may be provided that the copper layer is structured. Structuring is preferably understood to mean recesses in the copper layer, which separate individual portions of the copper layer from one another and thus electrically isolate them from one another. Such structuring is usually created by etching techniques.

The copper layer has an upper face. The upper face of the copper layer is preferably the face of the copper layer that faces away from the ceramic body, in particular the primary boundary surface of the ceramic body. Accordingly, the upper face of the copper layer is preferably the face of the copper layer that is provided for the bonded connection to an electronic component.

The upper face of the copper layer is preferably designed such that it can be firmly bonded to an electronic component using sintering material comprising silver. For this purpose, the upper face of the copper layer preferably has a special energy spectrum during an analysis by X-ray photoelectron spectroscopy.

An energy spectrum, which is obtained during an analysis of the upper face of the copper layer by X-ray photoelectron spectroscopy, exhibits: (i) at least one signal S1 which comprises at least one peak P1 with a maximum ranging from 526 eV-538 eV, wherein the at least one peak P1 has an area PF1, and the areas PF1 of all of the peaks P1 of the at least one signal S1 result in a total area GF1, and (ii) at least one signal S2 which comprises at least one peak P2 with a maximum ranging from 0 eV-1400 eV, wherein the at least one peak P2 has an area PF2, and the areas PF2 of all of the peaks P2 of the at least one signal S2 result in a total area GF2, the ratio GF1/GF2 being at least 0.25.

The energy spectrum preferably comprises the range from 0 eV-1400 eV.

The energy spectrum exhibits at least one signal S1. It can therefore also have a plurality of signals S1.

The at least one signal S1 comprises at least one peak P1 with a maximum ranging from 526 eV-538 eV. Accordingly, a peak P1 is characterized by having a maximum ranging from 526 eV-538 eV.

The energy spectrum can therefore, for example, exhibit a signal S1 comprising one or more peaks P1. On the other hand, the energy spectrum can also exhibit a plurality of signals S1, each of which comprises one or more peaks P1.

The at least one peak P1 has an area PF1, wherein the areas PF1 of all peaks P1 of the at least one signal S1 result in a total area GF1. For example, if the energy spectrum exhibits a plurality of signals S1, each of which has a plurality of peaks P1, the total area GF1 results from the sum of the areas PF1 of all peaks P1.

A peak P1 with a maximum ranging from 526 eV-538 eV indicates the presence of oxygen species. The oxygen species may, for example, be a species selected from the group consisting of copper oxides (for example copper(I) oxide, copper (II) oxide), copper hydroxides and organic compounds.

The total area GF1 therefore correlates with the proportion of oxygen species on the upper face of the copper layer of the copper-ceramic substrate.

The energy spectrum exhibits at least one signal S2. It can therefore also have a plurality of signals S2.

The at least one signal S2 comprises at least one peak P2 with a maximum ranging from 0 eV-1400 eV. Accordingly, a peak P2 is characterized by having a maximum ranging from 0 eV-1400 eV. The at least one signal S2 may in particular also comprise at least one signal S2 as described herein as signal S1 (for example, a signal comprising at least one peak with a maximum ranging from 526 eV-538 eV). Consequently, the signal S2 also comprises the signal S1.

The energy spectrum can therefore, for example, exhibit a signal S2 comprising one or more peaks P2. On the other hand, the energy spectrum can also exhibit a plurality of signals S2, each of which comprises one or more peaks P2.

The at least one peak P2 has an area PF2, wherein the areas PF2 of all peaks P2 of the at least one signal S2 result in a total area GF2. For example, if the energy spectrum exhibits a plurality of signals S2, each of which comprises a plurality of peaks P2, the total area GF2 results from the sum of the areas PF2 of all peaks P2.

Typically, the energy spectrum exhibits a plurality of signals S2.

The energy spectrum exhibits a signal S2 as described herein as signal S1 (for example, a signal comprising at least one peak with a maximum ranging from 526 eV-538 eV). Therefore, a signal S2 comprises at least one peak P2 with a maximum ranging from 526 eV-538 eV, which indicates the presence of oxygen species. The oxygen species may, for example, be a species selected from the group consisting of copper oxides, copper hydroxides and organic compounds.

Furthermore, the energy spectrum preferably exhibits a further signal S2 which comprises at least one further peak P2.

A further signal S2 may, for example, indicate the Cu2p region of the energy spectrum and therefore comprise at least one peak P2 indicating the presence of a copper species. The copper species can be, for example, copper(I) oxide, copper (II) oxide, metallic copper or copper hydroxide.

A further signal S2 may, for example, comprise a peak P2 which indicates the presence of a carbon species. The carbon species can, for example, be an adsorptive to the copper (e.g. carbon dioxide from the ambient air) or common organic impurities.

A further signal S2 may, for example, comprise a peak P2 which indicates the presence of a further species. The further species can, for example, be a nitrogen species that accumulates on the upper face of the copper layer during the production of the copper-ceramic substrate.

The total area GF2 therefore correlates with the proportion of copper species in the upper face of the copper layer of the copper-ceramic substrate.

The ratio GF1/GF2 is at least 0.25.

According to a preferred embodiment, the ratio GF1/GF2 is at least 0.29.

According to a further preferred embodiment, the ratio GF1/GF2 is not more than 0.46 and particularly preferably not more than 0.40.

According to a further preferred embodiment, the ratio GF1/GF2 ranges from 0.25-0.46 and particularly preferably ranges from 0.29-0.40.

Surprisingly, it has been found that a copper-ceramic substrate which is designed such that an energy spectrum, which is obtained during an analysis of the upper face of the copper layer by X-ray photoelectron spectroscopy, exhibits (i) at least one signal S1 which comprises at least one peak P1 with a maximum ranging from 526 eV-538 eV, wherein the at least one peak P1 has an area PF1, and the areas PF1 of all of the peaks P1 of the at least one signal S1 result in a total area GF1, and (ii) at least one signal S2 which comprises at least one peak P2 with a maximum ranging from 0 eV-1400 eV, wherein the at least one peak P2 has an area PF2, and the areas PF2 of all of the peaks P2 of the at least one signal S2 result in a total area GF2, the ratio GF1/GF2 being at least 0.25, can be firmly bonded to an electronic component using sintering material comprising silver.

Without wishing to be bound by any theory, this could be due to the presence of oxygen species at a minimum concentration on the upper face of the copper layer. Conventional prior-art copper-ceramic substrates readily passivate through contact with an oxygen-containing atmosphere. The presence of this passivation layer appears to be sufficient for the formation of a sintered bond between the copper layer of the copper-ceramic substrate and an electronic component. The copper-ceramic substrate according to the invention is such that an energy spectrum, which is obtained during an analysis of the upper face of the copper layer by X-ray photoelectron spectroscopy, exhibits (i) at least one signal S1 which comprises at least one peak P1 with a maximum ranging from 526 eV-538 eV, wherein the at least one peak P1 has an area PF1, and the areas PF1 of all of the peaks P1 of the at least one signal S1 result in a total area GF1, and (ii) at least one signal S2 which comprises at least one peak P2 with a maximum ranging from 0 eV-1400 eV, wherein the at least one peak P2 has an area PF2, and the areas PF2 of all of the peaks P2 of the at least one signal S2 result in a total area GF2, the ratio GF1/GF2 being at least 0.25. A copper-ceramic substrate comprising a copper layer, the upper face of which has such an energy spectrum, contains a high proportion of oxygen species. Such a high proportion of oxygen species, in contrast to a lower proportion of oxygen species, as is present on the upper face of the copper layer of conventionally passivated copper-ceramic substrates or copper-ceramic substrates that are thermally passivated in a practice standard in the field, seems, quite surprisingly, to promote the formation of a sintered bond between the copper layer of the copper-ceramic substrate and an electronic component. Furthermore, it has surprisingly been shown that a particularly high bond strength can be achieved when the ratio GF1/GF2 ranges from 0.25-0.46.

According to a further preferred embodiment, an energy spectrum, which is obtained during an analysis of the upper face of the copper layer by X-ray photoelectron spectroscopy, exhibits at least one signal S2 comprising at least one peak P2a with a maximum ranging from 933.2 eV-934.0 eV.

A signal S2, which comprises a peak P2a with a maximum ranging from 933.2 eV-934.0 eV, indicates the presence of copper (II) oxide (CuO) on the upper face of the copper layer.

According to a preferred embodiment, the upper face of the copper layer is designed such that an energy spectrum, which is obtained during an analysis of the upper face of the copper layer by X-ray photoelectron spectroscopy, exhibits at least one signal S2 which comprises at least one peak P2b with a maximum ranging from 932.2 eV-932.8 eV, wherein peak P2a occupies an area F2a and peak P2b occupies an area F2b and the ratio of area F2a to area F2b is at least 0.4.

A signal S2 comprising at least one peak P2b with a maximum ranging from 932.2 eV-932.8 eV indicates the presence of copper(I) oxide (Cu₂O) and/or metallic copper (Cu(0)) on the upper face of the copper layer. The signal S2 can therefore also have a plurality of peaks P2b, for example a peak P2b indicating the presence of copper(I) oxide (Cu₂O) and a peak P2b indicating the presence of metallic copper (Cu(0)). The area F2b preferably comprises the area of all peaks P2b with a maximum ranging from 932.2 eV-932.8 eV. The area F2b is therefore preferably the sum of the areas of all peaks P2b with a maximum ranging from 932.2 eV-932.8 eV.

Accordingly, the area F2a of the peak P2a correlates with the proportion of copper (II) oxide (CuO) on the upper face of the copper layer. In contrast, the area F2b of the at least one peak P2b correlates with the proportion of copper(I) oxide (Cu₂O) and/or metallic copper (Cu(0)) on the upper face of the copper layer.

According to a preferred embodiment, the ratio of area F2a to area F2b is at least 0.5, particularly preferably at least 5.0 and very particularly preferably at least 8.0.

According to a further preferred embodiment, the ratio of area F2a to area F2b is not more than 1000, more preferably not more than 500, particularly preferably not more than 100, very particularly preferably not more than 50 and in particular not more than 30.

According to a preferred embodiment, the ratio of area F2a to area F2b ranges from 0.4-1000, more preferably ranges from 0.5-500, particularly preferably ranges from 5.0-100 and very particularly preferably ranges from 8.0-30.

Surprisingly, it has been found that a copper-ceramic substrate which is designed such that an energy spectrum, which is obtained during an analysis of the upper face of the copper layer by X-ray photoelectron spectroscopy, exhibits a signal which comprises at least one peak P2a with a maximum ranging from 933.2 eV-934.0 eV, can be firmly bonded to an electronic component using sintering material comprising silver.

Without wishing to be bound by any theory, this could be due to the presence of copper (II) oxide (CuO) on the upper face of the copper layer. Conventional prior-art copper-ceramic substrates readily passivate through contact with an oxygen-containing atmosphere. It has been found that copper(I) oxide (Cu₂O) is predominantly formed on the upper face of the copper layer. The presence of copper(I) oxide (Cu₂O) does not seem to be conducive to the formation of a sintered bond between the copper layer of the copper-ceramic substrate and an electronic component. According to a preferred embodiment, the copper-ceramic substrate is such that an energy spectrum, which is obtained during an analysis of the upper face of the copper layer by X-ray photoelectron spectroscopy, exhibits at least one signal comprising at least one peak P2a with a maximum ranging from 933.2 eV-934.0 eV. This peak P2a indicates the presence of copper (II) oxide (CuO). In contrast to copper(I) oxide (Cu₂O), copper (II) oxide (CuO) surprisingly appears to promote the formation of a sintered bond between the copper layer of the copper-ceramic substrate and an electronic component.

Furthermore, it was surprisingly found that a particularly strong bonded connection of a copper-ceramic substrate to an electronic component can be achieved using sintering material if the upper face of the copper layer is designed such that an energy spectrum, which is obtained during an analysis of the upper face of the copper layer by X-ray photoelectron spectroscopy, exhibits at least one signal which comprises at least one peak P2b with a maximum ranging from 932.2 eV-932.8 eV, wherein peak P2a occupies an area F2a and peak P2b occupies an area F2b and the ratio of area F2a to area F2b is at least 0.4.

Without wishing to be bound by any theory, this could be due to the fact that in this case the proportion of copper (II) oxide (CuO) to copper(I) oxide (Cu₂O) and metallic copper (Cu(0)) is elevated on the upper face of the copper layer. While a peak P2a with a maximum at 933.2-934.0 eV indicates the presence of copper (II) oxide (CuO), at least one peak P2b with a maximum ranging from 932.2 eV-932.8 eV indicates the presence of copper(I) oxide (Cu₂O) and metallic copper (Cu(0)). Since the presence of copper (II) oxide (CuO) has an advantageous effect on the formation of a bonded connection between the upper face of the copper-ceramic substrate and an electronic component using sintering material, this effect seems to be greater the higher the proportion of copper (II) oxide (CuO) relative to copper(I) oxide (Cu₂O) and metallic copper (Cu(0)) on the upper face of the copper layer. A particularly high bond strength is ultimately achieved when a certain proportion of copper (II) oxide (CuO) relative to copper(I) oxide (Cu₂O) and metallic copper (Cu(0)) is not exceeded, so that the ratio of area F2a to area F2b ranges from 0.4-1000.

According to a preferred embodiment, the copper-ceramic substrate comprises a further (second) copper layer which is connected in a planar manner to the ceramic body. The further copper layer is preferably connected in a planar manner to the boundary surface facing away from the primary boundary surface of the ceramic (and preferably running in parallel therewith). The further (second) copper layer can be of the same nature as the (first) copper layer or can differ in its properties from the (first) copper layer. For the properties of the further (second) copper layer, reference is made to the above explanations.

The method for producing the copper-ceramic substrate according to the invention is not further limited.

Preferably, the method for producing the copper-ceramic substrate according to the invention comprises the steps of:
(a) providing a copper-ceramic substrate comprising
   (i) a ceramic body and
   (ii) a copper layer which is connected to the ceramic body in a planar manner, wherein the copper layer has an upper face, and
(b) treating the upper face of the copper layer of the copper-ceramic substrate such that an energy spectrum, which is obtained during an analysis of the upper face of the copper layer by X-ray photoelectron spectroscopy, exhibits
   (i) at least one signal S1 which comprises at least one peak P1 with a maximum ranging from 526 eV-538 eV, wherein the at least one peak P1 has an area PF1, and the areas PF1 of all of the peaks P1 of the at least one signal S1 result in a total area GF1, and
   (ii) at least one signal S2 which comprises at least one peak P2 with a maximum ranging from 0 eV-1400 eV, wherein the at least one peak P2 has an area PF2, and the areas PF2 of all of the peaks P2 of the at least one signal S2 result in a total area GF2,
   the ratio GF1/GF2 being at least 0.25.

The method for producing the copper-ceramic substrate according to the invention preferably comprises providing a copper-ceramic substrate comprising (i) a ceramic body and (ii) a copper layer which is connected to the ceramic body in a planar manner, wherein the copper layer has an upper face.

The copper-ceramic substrate can be a standard copper-ceramic substrate. The copper-ceramic substrate therefore preferably comprises a ceramic body and a copper layer which is connected to the ceramic body in a planar manner, wherein the copper layer has an upper face. For the properties of the copper-ceramic substrate and its components, reference can be made to the above information. However, the upper face of the copper layer preferably does not meet the requirement that an energy spectrum, which is obtained during an analysis of the upper face of the copper layer by X-ray photoelectron spectroscopy, exhibits (i) at least one signal S1 which comprises at least one peak P1 with a maximum ranging from 526 eV-538 eV, wherein the at least one peak P1 has an area PF1, and the areas PF1 of all of the peaks P1 of the at least one signal S1 result in a total area GF1, and (ii) at least one signal S2 which comprises at least one peak P2 with a maximum ranging from 0 eV-1400 eV, wherein the at least one peak P2 has an area PF2, and the areas PF2 of all of the peaks P2 of the at least one signal S2 result in a total area GF2, the ratio GF1/GF2 being at least 0.25.

The method for producing the copper-ceramic substrate according to the invention preferably comprises cleaning the upper face of the copper layer of the copper-ceramic substrate.

The cleaning is carried out, for example, by exposing the upper face of the copper layer of the copper-ceramic substrate to a reducing organic compound. The reducing organic compound can, for example, be formic acid.

The method for producing the copper-ceramic substrate according to the invention preferably comprises treating the upper face of the copper layer of the copper-ceramic substrate so that an energy spectrum, which is obtained during an analysis of the upper face of the copper layer by X-ray photoelectron spectroscopy, exhibits (i) at least one signal S1 which comprises at least one peak P1 with a maximum ranging from 526 eV-538 eV, wherein the at least one peak P1 has an area PF1, and the areas PF1 of all of the peaks P1 of the at least one signal S1 result in a total area GF1, and (ii) at least one signal S2 which comprises at least one peak P2 with a maximum ranging from 0 eV-1400 eV, wherein the at least one peak P2 has an area PF2, and the areas PF2 of all of the peaks P2 of the at least one signal S2 result in a total area GF2, the ratio GF1/GF2 being at least 0.25.

The treatment of the upper face of the copper layer of the copper-ceramic substrate is not further restricted. The treatment of the upper face of the copper layer of the copper-ceramic substrate preferably comprises a plasma treatment of the upper face of the copper layer or the deposition of a copper oxide on the upper face of the copper layer.

According to a preferred embodiment, the treatment of the upper face of the copper layer of the copper-ceramic substrate comprises a plasma treatment.

Plasma is preferably understood to mean a partially ionized gas which particularly preferably comprises highly excited particles and radicals. Plasma is preferably capable of causing oxidation on the upper face of the copper layer of the copper-ceramic substrate. Copper (II) oxide is preferably formed in the process.

According to a particularly preferred embodiment, the plasma treatment is carried out with an oxygen plasma. The oxygen plasma can be generated in a manner customary in the art. For this purpose, for example, the AP-600 plasma system (Nordson-March) can be used.

The plasma treatment is preferably carried out at a high-frequency power ranging from 200-1000 W and particularly preferably at a high-frequency power ranging from 500-700 W, for example at 600 W.

The plasma treatment is preferably carried out at a frequency ranging from 10-15 MHz and particularly preferably at a frequency ranging from 13-14 MHz, for example at a frequency of 13.56 MHz.

According to a preferred embodiment, the plasma treatment is carried out at a base pressure ranging from 0.1-0.5 mbar and particularly preferably at a base pressure ranging from 0.2-0.4 mbar.

According to a preferred embodiment, the plasma treatment is carried out at a process pressure ranging from 0.5-1.5 mbar and particularly preferably at a process pressure ranging from 0.7-1.0 mbar.

According to a preferred embodiment, the oxygen gas flow after reaching the base pressure ranges from 50-150 standard cubic centimeters per minute, for example 100-150 standard cubic centimeters per minute.

The plasma treatment is preferably carried out for a period of time ranging from 100-1000 s and particularly preferably for a period of time ranging from 150-900 s.

According to a further preferred embodiment, the treatment of the upper face of the copper layer of the copper-ceramic substrate comprises the deposition of a copper oxide on the upper face of the copper layer. The copper oxide may preferably be copper (II) oxide. Preferably, the copper oxide is deposited on the upper face of the copper layer of the copper-ceramic substrate by a method customary in the art, for example by sputtering.

The copper-ceramic substrate according to the invention is preferably used for bonded connection to an electronic component.

An electronic component is preferably understood to mean an electronic or electrical part. The electronic component is preferably selected from the group consisting of semiconductor components. The semiconductor components are preferably selected from the group consisting of transistors, diodes, and integrated circuits.

According to a preferred embodiment, the electronic component comprises a metal coating. The metal coating can be used to facilitate easier bonding of the electronic component to the copper-ceramic substrate via the sintering material. The metal coating may preferably comprise different layers. The metal coating of the electronic component preferably comprises a precious metal. The precious metal can be part of an alloy containing precious metals. The precious metal preferably comprises at least one element which is selected from the group consisting of gold, silver and palladium. According to a preferred embodiment, the metal coating of the electronic component comprises silver or an alloy containing at least one element selected from the group consisting of nickel, palladium and gold.

According to a preferred embodiment, the copper-ceramic substrate is also suitable for bonded connection to an electronic component. Therefore, the upper face of the copper-ceramic substrate is preferably not in contact with a connecting layer which has formed a bonded connection to a further part, particularly preferably an electronic component.

The invention provides a method for producing a bonded connection between a copper-ceramic substrate and an electronic component, in which:
a) providing a copper-ceramic substrate comprising (a) a ceramic body and (b) a copper layer which is connected to the ceramic body in a planar manner, wherein the copper layer has an upper face, wherein an energy spectrum, which is obtained during an analysis of the upper face of the copper layer by X-ray photoelectron spectroscopy, exhibits (i) at least one signal S1 which comprises at least one peak P1 with a maximum ranging from 526 eV-538 eV, wherein the at least one peak P1 has an area PF1, and the areas PF1 of all of the peaks P1 of the at least one signal S1 result in a total area GF1, and (ii) at least one signal S2 which comprises at least one peak P2 with a maximum ranging from 0 eV-1400 eV, wherein the at least one peak P2 has an area PF2, and the areas PF2 of all of the peaks P2 of the at least one signal S2 result in a total area GF2, the ratio GF1/GF2 being at least 0.25,
b) an electronic component is provided,
c) a sintering material comprising silver is provided,
d) the electronic component, the copper-ceramic substrate and the sintering material are positioned so as to create an arrangement in which the electronic component is in contact with the upper face of the copper layer of the copper-ceramic substrate via the sintering material, and
e) the arrangement is subjected to a treatment which creates a sintered bond between the electronic component and the copper-ceramic substrate.

In the method, a copper-ceramic substrate is provided.

The copper-ceramic substrate is a copper-ceramic substrate as described herein.

Accordingly, the copper-ceramic substrate comprises
a) a ceramic body and
b) a copper layer which is connected to the ceramic body in a planar manner, wherein the copper layer has an upper face,
wherein
an energy spectrum, which is obtained during an analysis of the upper face of the copper layer by X-ray photoelectron spectroscopy, exhibits
(i) at least one signal S1 which comprises at least one peak P1 with a maximum ranging from 526 eV-538 eV, wherein the at least one peak P1 has an area PF1, and the areas PF1 of all of the peaks P1 of the at least one signal S1 result in a total area GF1, and
(ii) at least one signal S2 which comprises at least one peak P2 with a maximum ranging from 0 eV-1400 eV, wherein the at least one peak P2 has an area PF2, and the areas PF2 of all of the peaks P2 of the at least one signal S2 result in a total area GF2,
the ratio GF1/GF2 being at least 0.25.

In the method, an electronic component is provided.

For the properties of the electronic component, reference can be made to the above information.

In the method, a sintering material comprising silver is provided.

The sintering material comprising silver is preferably selected from the group consisting of sintering pastes, sintering films and sintering preforms.

According to a preferred embodiment the sintering material comprises a sintering paste. The sintering paste is preferably a sintering paste customary in the art. Preferably, the sintering paste comprises silver and an organic compound. It may be preferred that the silver in the sintering paste is present as silver particles. The silver particles can assume any shape and can therefore be present, for example, as spherical silver particles, silver flakes or irregularly shaped silver particles. The organic compound is preferably selected from the group consisting of dispersants, binders, fatty acids, and mixtures thereof. The dispersant can be selected from dispersants that are customary in the art. An exemplary dispersant is terpineol. The binders can be selected from polymers that are customary in the art. Examples include cellulose derivatives, for example methylcellulose, ethylcellulose, ethylmethylcellulose, carboxycellulolose and hydroxypropylcellulolose. The fatty acids can be selected from fatty acids that are customary in the art. The fatty acids are preferably selected from the group consisting of caprylic acid (octanoic acid), capric acid (decanoic acid), lauric acid (dodecanoic acid), myristic acid (tetradecanoic acid), palmitic acid (hexadecanoic acid), margaric acid (heptadecanoic acid), stearic acid (octadecanoic acid), arachidic acid (eicosanoic acid/icosanoic acid), behenic acid (docosanoic acid) and lignoceric acid (tetracosanoic acid).

According to a further preferred embodiment, the sintering material comprises a sintering film. Preferably, the sintering film is a sintering film customary in the art, as disclosed, for example, in European patent application EP3154729 A1. A sintering film can therefore have, for example, a sintering paste which comprises metal particles (in particular silver particles) and a binder which is present pre-dried on a carrier substrate. The sintering film can, for example, have a thickness ranging from 5-300 μm.

According to a further preferred embodiment, the sintering material comprises a sintering preform. Preferably, the sintering preform is a conventional sintering preform as disclosed, for example, in European patent application EP2428293 A2.

In the method, an electronic component is provided.

For the properties of the electronic component, reference can be made to the above information.

In the method, the electronic component, the copper-ceramic substrate and the sintering material are positioned so as to create an arrangement in which the electronic component is in contact with the upper face of the copper layer of the copper-ceramic substrate via the sintering material.

The method for creating the arrangement is not further limited.

According to a preferred embodiment, in this respect the sintering material is applied to the upper face of the copper layer of the copper-ceramic substrate. The sintering material can be applied to the upper face of the copper layer of the copper-ceramic substrate using methods customary in the art. Preferably, the sintering material is applied in the case of a sintering paste by jetting, dispensing, spraying, brushing, dabbing, dipping or printing, in particular screen printing or stencil printing, and in the case of a sintering film or a sintering preform by simply laying on said sintering material. Thereafter, the electronic component can be positioned with the upper face to be connected on the sintering material in order to create an arrangement in which the electronic component is in contact with the upper face of the copper layer of the copper-ceramic substrate via the sintering material.

According to an alternative preferred embodiment, the sintering material is applied to the upper face of the electronic component to be connected. The sintering material can be applied to the upper face of the electronic component to be connected using methods customary in the art. Preferably, the sintering material is applied in the case of a sintering paste by jetting, dispensing, spraying, brushing, dabbing, dipping or printing, in particular screen printing or stencil printing, and in the case of a sintering film or a sintering preform by simply laying on said sintering material. Thereafter, the copper-ceramic substrate can be positioned with the upper face of the copper layer on the sintering material in order to create an arrangement in which the electronic component is in contact with the upper face of the copper layer of the copper-ceramic substrate via the sintering material.

In the method, the arrangement is subjected to a treatment that creates a sintered bond between the electronic component and the copper-ceramic substrate.

According to a preferred embodiment, the treatment is carried out by applying temperature and/or pressure.

In the case of temperature application, the arrangement is preferably exposed to a temperature ranging from 150-350° C., more preferably to a temperature ranging from 180-280° C. and particularly preferably to a temperature ranging from 200-250° C.

In the case of pressure application, the arrangement is preferably exposed to a pressure ranging from >0-300 bar, particularly preferably a pressure ranging from 0.1-30 bar and very particularly preferably a pressure ranging from 0.2-10 bar.

The method creates a sintered bond and thus a bonded connection between the electronic component and the copper-ceramic substrate.

### DESCRIPTION OF THE METHOD

The analysis of the upper face of the copper layer by X-ray photoelectron spectroscopy, the recording of the energy spectrum and the evaluation of the energy spectrum are preferably carried out according to the following method:

In preparation for the measurements using X-ray photoelectron spectroscopy, the copper-ceramic substrates were cut with a side cutter into sample pieces with edge lengths of 0.9 (+/−0.1) cm×1.4 (+/−0.1) cm. Fringes on the edges after trimming were removed using a scalpel to ensure a straight support surface. The sample pieces were cleaned of dust by blowing on them with nitrogen gas. The sample pieces were glued to a sample holder using non-conductive adhesive tape.

The X-ray photoelectron spectra were recorded on a PHI VersaProbe4 from Physical Electronics with an AI anode (monochromatic Kα=1.487 keV) as the source. First, overview spectra (range 0-1400 eV) of the sample pieces were recorded. From the overview spectra, conclusions were drawn about the elements present on the examined upper side of the sample pieces. Detail spectra of the sample pieces were then recorded in the energy ranges in which signals could be identified in the overview spectrum. To record the detail spectra, an X-ray beam (200 μm diameter; 50 W at 15 kV; measurement time: 25-40 min (for example: 30 min); 20 ms integration time per measurement point) was used with the peak-to-noise setting activated and using a neutralizer (combination of Ar+ and e−, with low kinetic energy).

The spectra were evaluated using the analysis software CasaXPS (version 2.3.224PR1.0; Casa Software Ltd.). The C—C/C—H component of the C 1s signal (ubiquitously present) was normalized to 284.8 eV as a reference, and the binding energies of the detail spectra were shifted accordingly. A Shirley function was used for background correction. Peaks were generated from the obtained signals using the analysis software. The number of peaks was adjusted on the basis of fit models from the literature (XPS-NIST database), and the peaks were assigned to elements or compounds. The analysis software was used to calculate the peak areas for the generated peaks, taking into account the relative sensitivity factors.

### EXEMPLARY EMBODIMENTS

The present invention is described in more detail below by means of exemplary embodiments, which, however, should not be understood as limiting.

### Example 1

For the example, a copper-ceramic substrate measuring 27×38 mm was used, in which a ceramic body made of silicon nitride ceramic was connected on both faces to a copper layer with a thickness of 0.3 mm using an AMB (active metal brazing) method (Condura®.prime AMB, uncoated on the upper face, Heraeus).

The copper-ceramic substrate was first cleaned. For this purpose, the copper-ceramic substrate was first exposed to vacuum in the chamber of a soldering system (PINK Vadu 200), then to formic acid at an atmospheric pressure of 500 mbar and a temperature of 180° C. and then to nitrogen.

The copper-ceramic substrate was then subjected to a plasma treatment with an oxygen plasma. For this purpose, the copper-ceramic substrate was placed centrally on the upper sample carrier of the plasma system (AP-600 (Nordson-March). The plasma treatment was carried out for a process time of 180 s at a power of 600 W, a frequency of 13.56 Hz, a base pressure of 0.3 mbar and a process pressure of 0.9 mbar. After the plasma treatment, the copper-ceramic substrate was removed from the plasma system.

The upper face of the copper layer of the copper-ceramic substrates was analyzed by X-ray photoelectron spectroscopy according to the method described above. The results are shown in Table 1.

The copper-ceramic substrate was then fitted with silicon chips. For this purpose, the copper-ceramic substrate was printed with a sintering paste (ASP 338-28, Heraeus) using a 150 μm thick printing stencil and a squeegee. The sintering paste was pre-dried in a convection oven at 140° C. for 20 min in a nitrogen atmosphere with a residual oxygen content of 50 ppm and then cooled. Silicon chips measuring 4×4 mm (thickness=250 μm) with a bottom-face metallization (100 nm aluminum, 50 nm titanium, 100 nm nickel and finally 700 nm silver) were positioned on the pre-dried sintering paste. The sintering was carried out in a PINK sintering press (Pink, Wertheim) for a period of 3 min in a nitrogen atmosphere at a pressure of 20 MPa and a temperature of 250° C.

### Example 2

Example 2 was carried out in the same way as Example 1, but in contrast to Example 1, the plasma treatment was carried out for 300 s instead of 180 s.

### Example 3

Example 3 was carried out in the same way as Example 1, but in contrast to Example 1, the plasma treatment was carried out for 420 s instead of 180 s.

### Example 4

Example 4 was carried out in the same way as Example 1, but in contrast to Example 1, the plasma treatment was carried out for 600 s instead of 180 s.

### Example 5

Example 5 was carried out in the same way as Example 1, but in contrast to Example 1, the plasma treatment was carried out for 780 s instead of 180 s.

### Comparative Example 1

Comparative Example 1 was carried out in the same way as Example 1, but in contrast to Example 1, the cleaning with formic acid and the plasma treatment were omitted.

### Comparative Example 2

Comparative Example 1 was carried out in the same way as Example 1, but in contrast to Example 1, the plasma treatment was omitted.

### Evaluation

The components obtained in Examples 1-5 and Comparative Examples 1-2 were examined for mechanical bond strength of the silicon chips on the copper-ceramic substrates. For this purpose, a shear test was carried out using the bond tester Nordson Dage 4000 Plus (Nordson, USA). For this purpose, the component was first clamped into the fixture. For testing, a 6 mm wide steel shear chisel was used, which acted on the component with increasing force until the silicon chips were detached from the copper-ceramic substrates. The force at which the silicon chips detached was referred to as the shear strength and was specified to evaluate the bond strength in N mm². For the evaluation, 16 values were generated in each case and the mean value for the shear strength was calculated. The results are indicated in Table 1.

TABLE 1
Results of the bond strength test.

| | |
|---|---|
| GF1 / GF2 | Shear strength in N/mm² |

Examples

| | | |
|---|---|---|
| 1 | 0.35 | 76.6 |
| 2 | 0.37 | 78.7 |
| 3 | 0.39 | 76.2 |
| 4 | 0.39 | 74.5 |
| 5 | 0.43 | 59.0 |

Comparative examples

| | | |
|---|---|---|
| 1 | 0.23 | 54.9 |
| 2 | 0.24 | 57.6 |

The results show that the copper-ceramic substrates of Examples 1-5 according to the invention are clearly superior to the copper-ceramic substrates of Comparative Examples 1 and 2 with regard to their suitability for creating a strong, bonded connection to an electronic component.

1. A copper-ceramic substrate comprising
a) a ceramic body and
b) a copper layer which is connected to the ceramic body in a planar manner, wherein the copper layer has an upper face,
wherein
an energy spectrum, which is obtained during an analysis of the upper face of the copper layer by X-ray photoelectron spectroscopy, exhibits
(i) at least one signal S1 which comprises at least one peak P1 with a maximum ranging from 526 eV-538 eV, wherein the at least one peak P1 has an area PF1, and the areas PF1 of all of the peaks P1 of the at least one signal S1 result in a total area GF1, and
(ii) at least one signal S2 which comprises at least one peak P2 with a maximum ranging from 0 eV-1400 eV, wherein the at least one peak P2 has an area PF2, and the areas PF2 of all of the peaks P2 of the at least one signal S2 result in a total area GF2,
the ratio GF1/GF2 being at least 0.25.

2. The copper-ceramic substrate according to claim 1, wherein the ratio GF1/GF2 ranges from 0.25-0.46.

3. The copper-ceramic substrate according to claim 2, wherein the ratio GF1/GF2 ranges from 0.29-0.40.

4. The copper-ceramic substrate according to claim 1, wherein the ceramic of the ceramic body is selected from the group consisting of aluminum nitride ceramics, silicon nitride ceramics, and aluminum oxide ceramics.

5. A use of a copper-ceramic substrate according to claim 1 for bonded connection to an electronic component.

6. A method for producing a bonded connection between a copper-ceramic substrate and an electronic component, in which:
a) a copper-ceramic substrate according to claim 1 is provided,
b) an electronic component is provided,
c) a sintering material comprising silver is provided,
d) the electronic component, the copper-ceramic substrate and the sintering material are positioned so as to create an arrangement in which the electronic component is in contact with the upper face of the copper layer of the copper-ceramic substrate via the sintering material, and
e) the arrangement is subjected to a treatment which creates a sintered bond between the electronic component and the copper-ceramic substrate.
